(19) United States
(12) Patent Application Publication
(10) Pub. No.: US 2025/0365905 A1
(43) Pub. Date: Nov. 27, 2025

(54) DISPLAYER

(71) Applicant: DARWIN PRECISIONS CORPORATION, Hsinchu County (TW)

(72) Inventors: Chi-Chang Chen, Hsinchu County (TW); CHIA HSIN CHANG, Hsinchu County (TW)

(21) Appl. No.: 19/026,640

(22) Filed: Jan. 17, 2025

(30) Foreign Application Priority Data
May 22, 2024 (TW) 113118978

(51) Int. Cl. H05K 7/20; H05K 9/00

(52) U.S. Cl. CPC H05K 7/20972; H05K 9/0054

(57) ABSTRACT

A display includes a housing, a cover plate, a main board, a display module, and a heat exchanger. The housing has an opening and an accommodation space. The cover plate covers the opening. The main board is arranged in the accommodation space. The display module arranges in the accommodation space and electrically connects to the main board. The display module has a display side and a backside. The display side is located between the cover plate and the backside. The heat exchanger is located in the accommodation space which includes a first chamber and a second chamber. The display module separates the first chamber and the second chamber. The heat exchanger locates in the second chamber. The first chamber communicates to an outside of the housing having a first channel included the main board and the backside. The second chamber is not communicated to the outside of the housing.

### FIELD OF THE INVENTION

The present invention relates to a display device, and more particularly to a display device arranged outdoors.

### BACKGROUND OF THE INVENTION

Installing the display device outdoors as a billboard has various benefits, such as being easily identified at night or in the shadows, and making it easy to change the pattern on the billboard. However, since the outdoor environment is more susceptible to sunlight than the indoor environment and the display device itself generates heat, the heat dissipation design of the display device becomes extremely crucial.

In order to avoid the display module being directly exposed to the external environment, a window will be set up in the housing of the existing display device, and the window will be sealed with a transparent cover plate, and then the display module will be arranged behind the cover plate. However, such a setup will reduce the heat dissipation capacity of the display module. In addition, if the distance between the display module and the cover plate is increased so that airflow from the outside of the display device can enter the display device, dust, and other dirt may enter the gap between the display module and the cover plate, and the display quality will be reduced.

### SUMMARY OF THE INVENTION

The invention provides a display device, which has excellent heat dissipation performance and can prevent dust, dirt, or moisture from entering the space in front of the display module.

In order to achieve the above advantages, an embodiment of the present invention provides a display device, including a housing, a cover plate, a main board, a display module, and a heat exchanger. The housing has an accommodation space and an opening. The cover plate covers the opening. The main board is arranged in the accommodation space and opposite the cover plate. The display module is arranged in the accommodation space and electrically connected to the main board. The display module has a display side and a backside opposite to each other, and the display side is located between the cover plate and the backside. The heat exchanger is located in the accommodation space. The accommodation space includes a first chamber and a second chamber. The display module separates the first chamber and the second chamber. The heat exchanger is located in the second chamber. The first chamber is communicated to an outside of the housing and includes a first channel located between the main board and the backside. The second chamber is not communicated to the outside of the housing and includes a second channel located between the cover plate and the display side.

In one embodiment, the display module has a backlight assembly, and the main board is adapted for controlling the backlight assembly.

In one embodiment, the first channel completely separates the main board from the backside.

In one embodiment, the second chamber further includes a third channel located at a periphery of the backside, and the third channel surrounds the first chamber and communicates with the second chamber.

In one embodiment, the cover plate, the display module, and the main board are arranged along a first axis. The housing further has a third chamber in the accommodation space. The third chamber is on one side of the first chamber respective to a second axis perpendicular to the first axis and is adjacent to the heat exchanger. The third chamber is communicated to the outside of the housing and does not communicate to the first chamber and the second chamber.

In one embodiment, the above-mentioned heat exchanger includes a plurality of first flow channels spaced from each other and a plurality of second flow channels spaced from each other. The first flow channels and the second flow channels are arranged alternatively, the first flow channels are communicated to the second chamber, and the second flow channels are communicated to the third chamber.

In one embodiment, the display device includes a first fan and a second fan. The first fan is arranged in the third chamber, wherein the first fan is adapted for generating a first airflow flowing through the first flow channel. The second fan is arranged in the third chamber, wherein the second fan is adapted for generating a second airflow flowing through the second flow channel. A direction of the first airflow is opposite to a direction of the second airflow in the heat exchanger.

The invention also provides a display device, including a housing, a cover plate, a main board, a display module, and a heat exchanger. The housing has an accommodation space and an opening communicating with each other. The cover plate covers the opening. The main board is arranged in the accommodation space and opposite the cover plate. The display module is arranged in the accommodation space and electrically connected to the main board, wherein the display module has a display side and a backside opposite to each other, and the display side is located between the cover plate and the backside. The heat exchanger is located in the accommodation space. The accommodation space includes a first chamber and a second chamber separated from each other. The heat exchanger is located in the second chamber. The first chamber is communicated to an outside of the housing and includes a first channel located between the main board and the backside. The second chamber is not communicated to the outside of the housing and includes a second channel located between the cover plate and the display side. The display module includes a backlight assembly and a control assembly. The control assembly is arranged on the main board. And, the first channel completely separates the main board from the backside.

In one embodiment, the display module separates the first chamber and the second chamber. The backside is adjacent to the first channel. And, the display side is adjacent to the second channel.

With the above explanation, the display device of the present invention uses a display module to separate a first chamber communicated to the exterior of the housing and a second chamber located between the display module and the cover plate and not communicated to the exterior of the housing and discharges heat from the second chamber to the exterior of the housing by a heat exchanger. Therefore, both surfaces of the display module (the display side and the backside of the display module) which serve as a separator can dissipate heat and have good heat dissipation capability, and dust, dirt, or moisture, etc., can be prevented from entering into the second chamber between the display module and the cover plate, and the display quality is good. In addition, from another perspective, since the first channel in the first chamber separating the main board from the backside of the display module is provided in the first chamber that can be connected to the outside of the outer housing, and since the other side of the main board is close to the outside of the outer housing, both surfaces of the main board (or the space provided therein) can easily exchange heat with the outside of the outer housing, and thus have good heat dissipation performance.

Other objectives, features and advantages of the invention will be further understood from the further technological features disclosed by the embodiments of the invention wherein there are shown and described preferred embodiments of this invention, simply by way of illustration of modes best suited to carry out the invention.

### BRIEF DESCRIPTION OF THE DRAWINGS

The present invention will become more readily apparent to those ordinarily skilled in the art after reviewing the following detailed description and accompanying drawings, in which:

FIG. 1 is a three-dimensional schematic diagram of the backside of a display device in an embodiment of the present invention;

FIG. 2 is a schematic diagram of the decomposition of the display device in the embodiment of FIG. 1;

FIG. 3 is the schematic cross-sectional diagram taken along the line A-A in FIG. 1;

FIG. 4 is the schematic cross-sectional diagram taken along the line B-B in FIG. 1;

FIG. 5 is a three-dimensional schematic diagram of the first chamber after removing the second rear cover in FIG. 1;

FIG. 6 is a three-dimensional schematic diagram of the second chamber after removing the first rear cover in FIG. 1; and

FIG. 7 is a schematic diagram of the heat exchanger in the embodiment of FIG. 1.

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

In the following article, the terms used in the description of embodiments based on the present invention, such as the description of the orientation or positional relationship indicated by “up”, “down”, etc., are described according to the orientation or positional relationship shown in the schema used, and the above terms are only for convenience in describing the present invention and are not for limiting the present invention, That is, the components mentioned must not be indicated or implied to be in a specific orientation, constructed in a specific orientation. In addition, the terms “first” and “second” mentioned in this specification or in the scope of the patent application are only used to name the name of the component (element) or to distinguish different embodiments or scopes and are not used to limit the upper or lower limit on the number of components.

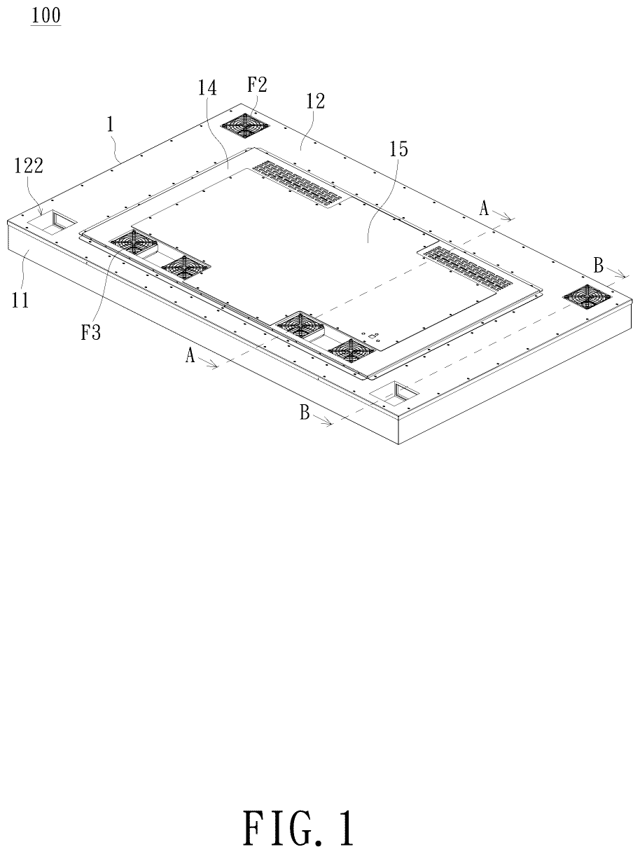

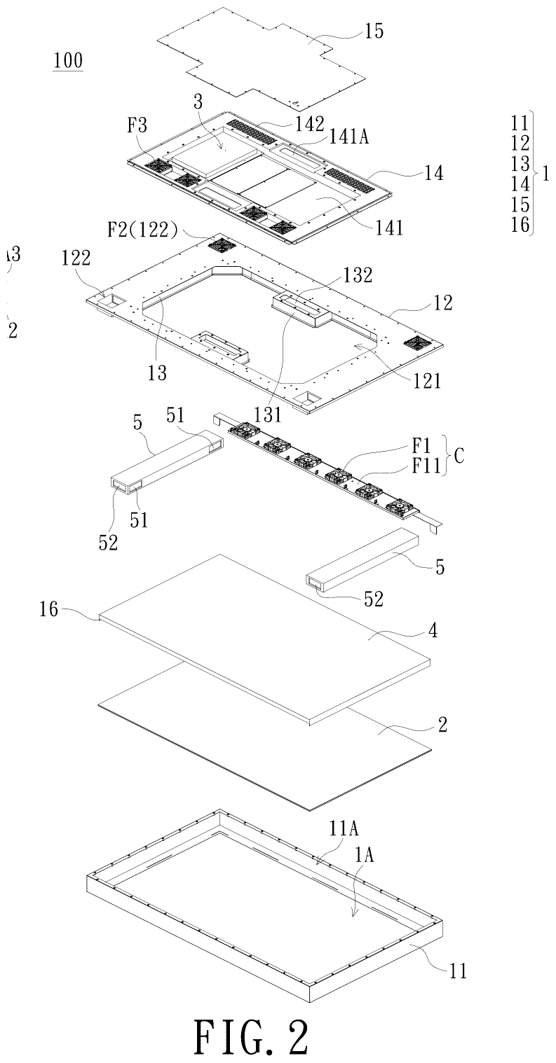

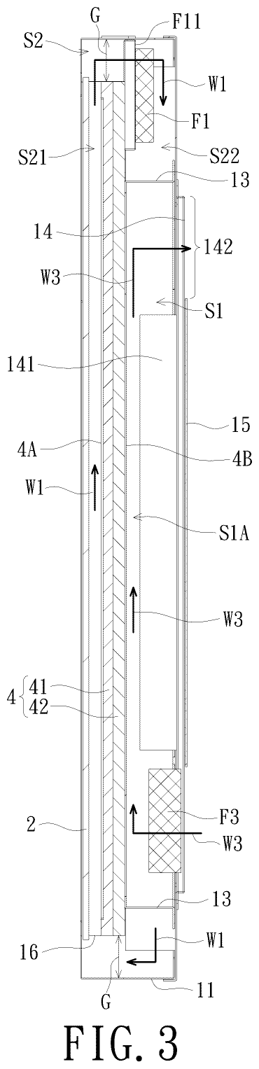

FIG. 1 is a three-dimensional schematic diagram of the backside of a display device in an embodiment of the present invention. FIG. 2 is a schematic diagram of the decomposition of the display device in the embodiment of FIG. 1. FIG. 3 is a schematic cross-sectional diagram taken along the line A-A in FIG. 1. Because FIG. 1 is the backside view of the display device 100, the front and rear directions of the display device 100 mentioned below are in the extending direction of the display device 100 in the figures (see the first axis A1 in the figures), the left and right directions mentioned below are in extending direction of the long axis of the display device 100 in the figures (see the second axis A2 in the figures), and the upper and lower directions are in the extending direction of the short axis of the device 100 shown in the figures (see the third axis A3 in the figures).

As shown in FIG. 1 to FIG. 3, a display device 100 in an embodiment includes a housing 1, a cover plate 2, a main board 3, a display module 4, and a heat exchanger 5. The housing 1 has an accommodation space S and an opening 1A communicated to each other. The cover plate 2 covers the opening 1A. The main board 3 is arranged in the accommodation space S and opposite to the cover plate 2. The display module 4 is arranged in the accommodation space S and electrically connected to the main board 3. The display module 4 has a display side 4A and a backside 4B opposite to each other, and the display side 4A is located between the cover plate 2 and the backside 4B (see FIG. 3). The heat exchanger 5 is located in the accommodation space S. As shown in FIG. 3, the accommodation space S includes a first chamber S1 and a second chamber S2. The display module 4 separates the first chamber S1 and the second chamber S2. The heat exchanger 5 is located in the second chamber S2. The first chamber S1 is communicated to outside of the housing 1 and includes a first channel S1A located between the main board 3 and the backside 4B (as shown in FIG. 2, the main board 3 is arranged in an accommodating groove 141 in FIG. 3). The second chamber S2 is not communicated to the outside of the housing 1 and includes a second channel S21 located between the cover plate 2 and the display side 4A.

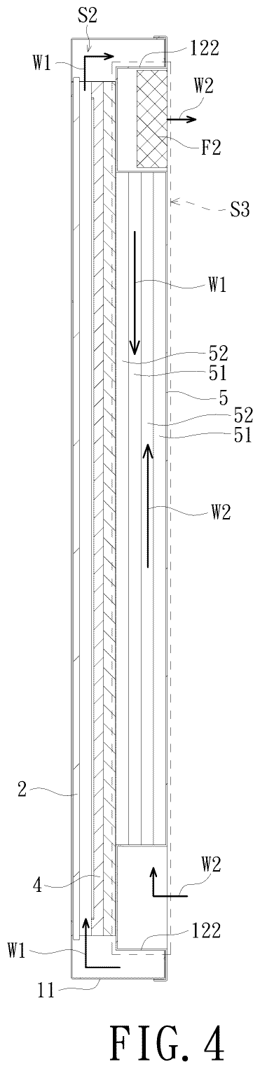

FIG. 4 is a schematic cross-sectional diagram taken along the line B-B in FIG. 1. As shown in FIG. 4, in the present embodiment, the accommodation space S further includes, for example, two third chambers S3. The third chamber S3 communicates with the outside of the housing 1, is adjacent to the second chamber S2, and can perform heat exchange with the second chamber S2 through the heat exchanger 5. In the present embodiment, the third chamber S3 is, for example, separated from the first chamber S1 and is not communicated to it, but not limited to this (see the description below). Because the specific position of each chamber (first chamber S1, second chamber S2, and third chamber S3) involves the design of the housing 1, the following describes the generation of airflow inside each chamber, and then specifies the shape of each chamber through the description of the structure of the housing 1.

As shown in FIG. 2, in the present embodiment, the display device 100 further includes, for example, a first fan F1, a second fan F2, and a third fan F3. The first fan F1 is adapted for generating a first airflow W1 in the second chamber S2 (see FIGS. 3 and 4, the first airflow W1 in FIG. 4 is located in first flow channel 51 that communicates with the second chamber S2 in the heat exchanger 5). Because the second chamber S2 is a sealed chamber, the first airflow W1 is a circulating airflow circulating in the second chamber S2. The second fan F2 is adapted for generating a second airflow W2 in the third chamber S3 (see FIG. 4, the second airflow W2 in FIG. 4 is in the second flow channel 52 that communicates with the third chamber S3 in the heat exchanger 5), and the second airflow W2 is a unidirectional airflow that enters the third chamber S3 (housing 1) from the outside of the housing 1 and then leaves the housing 1. The third fan F3 is adapted for generating a third airflow W3 in the first chamber S1, and the third airflow W3 is a unidirectional airflow that enters the housing 1 from the outside of the housing 1 and then leaves the housing 1.

Table 1 below describes the specifications of the position of each fan, the airflow generated, the chamber where the fan is located, the channels through which each airflow flows, and the flow channels through which each airflow flows.

TABLE 1

| | | | | The flow |
|---|---|---|---|---|
| | | | The channel in | channel |
| | | | which the airflow is | through which |
| | | | communicated | the airflow |
| | | The chamber to | (located in the | flows (located |
| The name of the | The generated | which the fan is | chamber, described | in heat |
| fan | airflow | communicated | later) | exchanger 5) |
| First fan F1 | First airflow W1 | Second chamber S2 | The second channel | First flow |
| | | | is S21 and the third | channel 51 |
| | | | channel is S22 | |
| Second fan F2 | Second airflow | Third chamber S3 | No specifically | Second flow |
| | W2 | | delineated and | channel 52 |
| | | | named | |
| Third fan F3 | Third airflow W3 | First chamber S1 | First channel S1A | The third |
| | | | | airflow W3 |
| | | | | does not flow |
| | | | | through the |
| | | | | heat exchanger 5 |

The specific configuration and shape of each structure of the display device 100 will be described hereinafter.

In the present embodiment, the cover plate 2 is a transparent plate body. There is no restriction on the material of cover plate 2, and it can be an existing material such as glass.

As shown in FIG. 2, the display module 4 is, for example, a plate-shaped component. The display module 4 includes, for example, a liquid crystal panel 41 and a backlight assembly 42, but the present invention does not limit the type of the display module 4. The liquid crystal panel 41 is located on the display side 4A, and the backlight assembly 42 is located on the backside 4B. In this embodiment, the functions of the display module 4, the first fan F1, the second fan F2, and the third fan F3 are all controlled by the main board 3, in other words, the main board 3 can be regarded as the control component of the display module 4 in the present embodiment, but the invention is not limited to this. In an embodiment not shown in the figures, the main board 3 may only control the first fan F1, the second fan F2, and the third fan F3, and the inside of the display module 4 or the backside of the backlight assembly 42 may be provided with a control assembly (not shown in the figures) for controlling the liquid crystal panel 41 and the backlight assembly 42, so that the display module 4 can display a pattern independently of the control of the main board 3.

As shown in FIG. 2, in this embodiment, the display module 4 is, for example, connected with a side plate 16 extending toward the cover plate 2 at the edges of two sides along the second axis A2 (the display module 4 is shown to be connected to the side plate 16 in FIG. 2). There is no restriction on the specific formation method of the side plate 16. The side plate 16 is adapted for forming a second channel S21 together with the display module 4 and the cover plate 2, wherein the second channel S21 is located between the display module 4 and the cover plate 2 and extends along the direction of the third axis A3 (see FIG. 3). The second channel S21 completely separates the cover plate 2 from the display side 4A of the display module 4. As shown in FIG. 3, on the third axis A3, the display module 4 has a gap G between the upper and lower part of the display module 4 and the inner wall surfaces of the housing 1, and the first airflow W1 flowing in the second chamber S2 can enter or leave the second channel S21 by the gaps G.

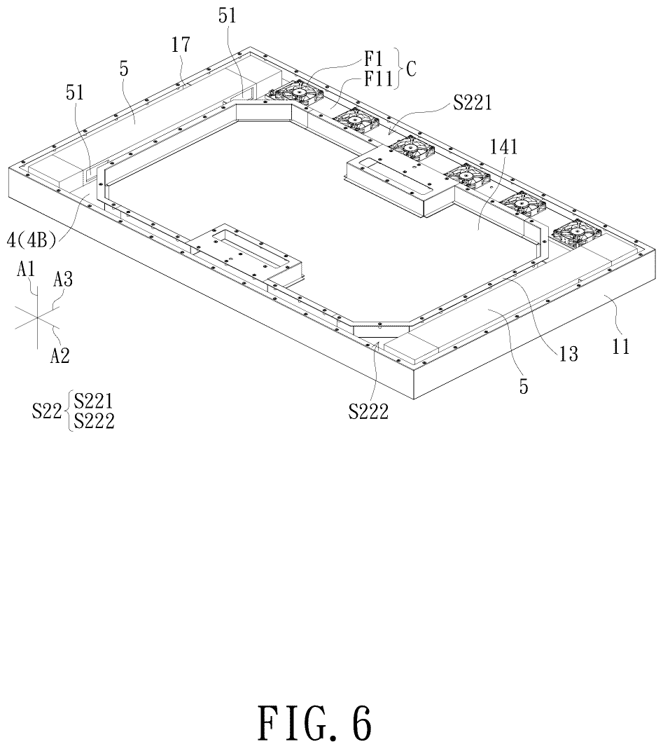

As shown in FIG. 2, in the present embodiment, the housing 1 includes, for example, a frame 11, a first rear cover 12, a surrounding wall 13, a second rear cover 14, a sub-cover plate 15, the side plate 16, and a partition plate 17 (see FIG. 6, located at two sides of the heat exchanger 5). The accommodation space S is the sum of a plurality of spaces surrounded by the frame 11, the first rear cover 12, the second rear cover 14, and the sub-cover plate 15. There is no restriction on the materials of the housing 1, which can be made of plastic or metal, etc., depending on the requirements.

The frame 11 has an opening 1A located in the front (below the first axis A1 in FIG. 2) and a rear opening 11A opposite to the opening 1A. The opening 1A is, for example, completely covered by the cover plate 2 when the frame 11 is assembled with the cover plate 2. The frame 11 constitutes, for example, a part of the front wall surface of the display device 100 (the part of the periphery of the cover plate 2) and the side wall surface, but is not limited to this.

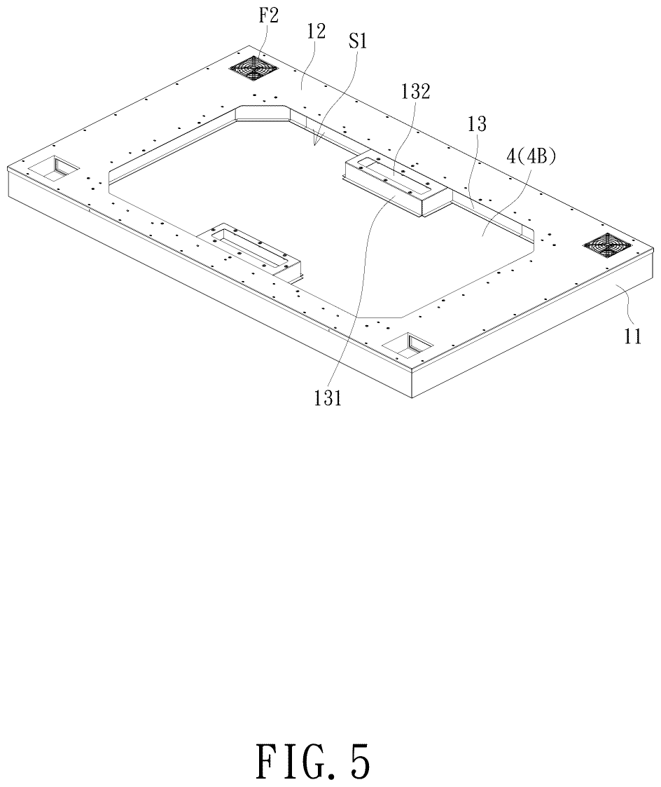

As shown in FIG. 2, the first rear cover 12 is adapted for covering the periphery of the rear opening 11A. The first rear cover 12 is, for example, an annular plate body and has a sub-opening 121 and a plurality of storage grooves 122. The sub-opening 121 is located in the center of the first rear cover 12. The size of the sub-opening 121 is, for example, smaller than the area size of the rear side of the display module 4, and the size of the sub-opening 121 also corresponds to the size of the second rear cover 14. FIG. 5 is a three-dimensional schematic diagram of the first chamber in FIG. 1 after removing the second rear cover. As shown in FIG. 5, when the first rear cover 12 covers the rear opening 11A, the backside 4B of the display module 4 can be seen from the sub-opening 121 (referring to FIG. 2), and the surrounding wall 13 in FIG. 5 surrounds the central part of the display module 4. The storage groove 122 is arranged near the sub-opening 121 and recessed toward the interior of the display device 100. The storage groove 122 is adapted for accommodating the second fan F2 and forms the wall surface of the third chamber S3.

As shown in FIG. 2, in the present embodiment, the two storage grooves 122 located on the same side of the sub-opening 121 (e.g., the two sub-openings 121 located on the left side of the second axis A2) each have an opening (not shown in the figures) facing each other, and the openings are adapted for assembling with the two ends of the heat exchanger 5 and can communicate with each other through the heat exchanger 5. Through this structure, the storage grooves 122 and heat exchanger 5 together form the third chamber S3. In addition, for the convenience of description, only two third fans F3 are shown in the figures, but it should be understandable that the number and detailed position of all fans (first fan F1, second fan F2, and third fan F3) in the display device 100 can be adjusted according to requirements.

As shown in FIGS. 2 and 3, the surrounding wall 13 surrounds the periphery of the sub-opening 121 and is located between the first rear cover 12 and the display module 4. The surrounding wall 13 is adapted for enclosing, with the frame 11, the cover plate 2, the first rear cover 12, and the display module 4 (part of the display module 4), a second chamber S2 that is sealed and not communicated to the outside of the housing 1. The second chamber S2 includes, in addition the second channel S21 located between the cover plate 2 and the display side 4A, a third channel S22 located between the peripheries of the main board 3 and the backside 4B of the display module 4 and surrounding the first chamber S1 (and the first channel S1A) by the surrounding wall 13. As shown in FIG. 3 and FIG. 6, the third channel S22 includes, for example, a first sub-channel S221 located on the third axis A3 and the upper side of the third channel (see FIG. 6) and a second sub-channel S222 located on the lower side of the third channel S22 (see FIG. 6). The first sub-channel S221 and the second sub-channel S222 are separated by the surrounding wall 13 and a partition plate 17 and communicated with each other through the first flow channels 51 inside the heat exchanger 5 (described later in detail). The partition plate 17 is, for example, a plurality of thin plates located on two sides of the heat exchanger 5. The part of the partition plate 17 close to the frame 11 is connected to the frame 11, and the part of the partition plate 17 close to the surrounding wall 13 is connected to the surrounding wall 13. It should be understood that there is no restriction on the specific structure of the partition plate 17, and in the embodiment not shown in the figures, the partition plate 17 can be, for example, a thin plate extending from two sides of the heat exchanger 5, or a plate extending in the frame 11, or a plate that can be assembled and disassembled between the heat exchanger 5 and the frame 11.

Referring to FIGS. 3, 4 and 6, by this structure, the first airflow W1 flowing through the second channel S21 in the second chamber S2 can enter the first sub-channel S221 through the gap between the display module 4 and the inner surface of the housing 1, and then flows into the heat exchanger 5 (the first flow channels 51) via the first sub-channel S221, and then re-enters into the second channel S21 through the second sub-channel S222 via gap G between the display module 4 and the inner wall of the housing 1 for recirculation, thereby removing the heat generated by the display module 4 from the periphery of the display side 4A between the cover 2 and the display side 4A of the display module 4 and the backside 4B of the display module 4.

In the present embodiment as shown in FIG. 2, in order to generate the first airflow W1, a plurality of first fans F1 are arranged on the mounting plate F11 and together form a fan assembly C extending along the second axis A2. As shown in FIG. 3, the fan assembly C is, for example, arranged to cover the gaps G and is located at the entrance of the first sub-channel S221 (located above the backside 4B of the display module 4 in FIG. 3) to generate the first airflow W1 moving upward from the bottom of the display module 4 in the second channel S21 by means of air pumping. Because the second chamber S2 is a sealed chamber, the second airflow W2 will circulate in the second chamber S2 and transfer heat to the wall surface of the heat exchanger 5 when flowing through the heat exchanger 5.

As shown in FIG. 2, in the present embodiment, the surrounding wall 13 further includes two protruding portions 131 opposite each other and protruding toward the center of the sub-opening 121. The protruding portions 131 are provided with wiring openings 132, and the wiring openings 132 are adapted for communicating with the accommodating groove 141 surrounded by the second rear cover 14 and allowing the display module 4 to be electrically connected to the main board 3, but the electrical connection means between the display module 4 and the main board 3 is not limited to this.

As shown in FIG. 2 to FIG. 5, in the present embodiment, the second rear cover 14 is adapted for covering the entire sub-opening 121 and forming a first chamber S1 (see FIGS. 2, 3, and 5) together with the surrounding wall 13, a part of the rear side of the display module 4 (the central part), and a sub-cover plate 15 covering the second rear cover 14. As shown in FIG. 2, the second rear cover 14 is, for example, provided with the accommodating groove 141 recessed toward the front of the display device 100 in the center, and the accommodating groove 141 is adapted for accommodating the main board 3, but the subject to be accommodated is not limited to this.

As shown in FIG. 2, the cover plate 2, display module 4, and the main board 3 are arranged along the first axis A1. The second rear cover 14 is provided with a through-hole part 142 on the upper side of the accommodating groove 141, and the through-hole part 142 has a plurality of through-holes. The second rear cover 14 is provided with a third fan F3 that communicates to two sides of the second rear cover 14 on the lower side of the accommodating groove 141.

As shown in FIG. 2, the accommodating groove 141 is provided with connecting ports 141A on the upper and lower sides of the interior corresponding to the positions of the wiring openings 132. As shown in FIG. 3, the depth of the accommodating groove 141 is, for example, less than the depth of the surrounding wall 13 so that there is a gap between the back plate of the display module 4 and the accommodating groove 141 to form the first channel S1A located in the first chamber S1. The first channel S1A completely separates the accommodating groove 141 from the rear side of the display module 4. The third fan F3 is adapted for pumping the air outside the housing 1 into the first chamber S1. The through-hole part 142 allows the air in the first chamber S1 to exit the first chamber S1 from the exterior of the housing 1 through the second rear cover 14. In this way, a portion of the heat generated by the display module 4 can be removed from the first chamber S1 by the backside 4B.

As shown in FIG. 2, in the present embodiment, the main board 3 is arranged in the accommodating groove 141. One side of the main board 3 is, for example, attached to the bottom of the accommodating groove 141 and therefore can transfer the heat generated by the main board 3 during operation to the plate at the bottom of the accommodating groove 141 (i.e., a wall surface on one side inside the first chamber S1). However, it should be understood that a heat transfer mechanism (such as a heat transfer block, heat dissipation paste, etc., not shown in the figures) may be provided or the size of the main board 3 may be changed so that the opposite sides of the main board 3 can directly transfer heat to the wall surface of the accommodating groove 141 by means of heat transfer. By this structure, one side surface of the main board 3 of the present invention can perform heat exchange through the air flowing through the first chamber S1, and the other side surface can perform heat exchange with the outside of the housing 1 through the sub-cover plate 15. From a point of view, because the accommodating groove 141 is recessed in the second rear cover 14 so that the wall surface of the entire accommodating groove 141 is surrounded by the first chamber S1 and the sub-cover plate 15 covering the accommodating groove 141 directly faces the outside of the housing 1, it can be considered that all surfaces of the accommodating groove 141 are directly or indirectly communicated with the outside of the housing 1.

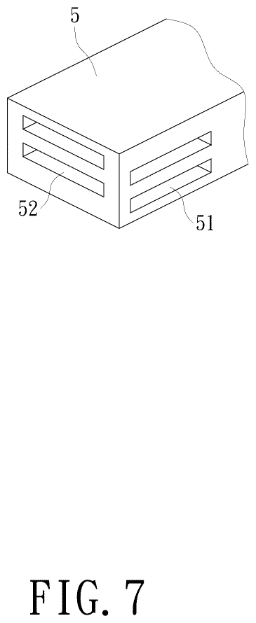

As shown in FIG. 2 and FIG. 7, in the present embodiment, the number of the heat exchangers 5 corresponds to the number of the third chambers S3 and is two, but is not limited to this. The heat exchanger 5 has, for example, a plurality of first flow channels 51 parallel to each other and a plurality of second flow channels 52 parallel to each other. The first flow channels 51 and the second flow channels 52 all extend along the extending direction of the third axis A3 in FIG. 2 and are not communicated with each other. The specific numbers of the first flow channels 51 and the second flow channels 52 can be adjusted according to the requirements. The entrance and exit of the first flow channels 51 (i.e., where the symbol of the first flow channels 51 in the figures) is located, for example, on one side of the heat exchanger 5 (the side facing the center of the display device 100 when arranged) and is communicated with the second chamber S2, and the entrance and exit of the second flow channel 52 (i.e., where the symbol of the second flow channels 52 in the figures) is located at the two ends of the long axis (extending along the third axis A3) of the heat exchanger 5 and is communicated with the third chamber S3, so that the entrance and exit direction of the first flow channel 51 and the entrance and exit direction of the second flow channel 52 are perpendicular to each other, but are not limited to this.

As shown in FIG. 4 and FIG. 7, in the present embodiment, the first flow channels 51 and the second flow channels 52 are arranged alternatively with each other, in other words, except the flow channels located at two ends of the heat exchanger 5, each first flow channel 51 is located between the two adjacent second flow channels 52, and each second flow channel 52 is located between the two adjacent first flow channels 51 so that the openings of the first flow channels 51 and the openings of the second flow channels 52 are at different heights.

As shown in FIG. 2, during assembly, the two heat exchangers 5 are respectively arranged between the two storage grooves 122 on the first rear cover 12 and are communicated with the storage grooves 122. By this configuration, the two storage grooves 122 can communicate with each other through the second flow channel 52 inside the heat exchanger 5 and together form a third chamber S3 (see FIG. 4). The heat exchanger 5 can transfer the thermal energy from the second chamber S2 to the third chamber S3 and then to the outside of the housing 1. Referring to FIG. 2 and comparing FIGS. 3 and 4, it can be seen that in the present embodiment, the two third chambers S3 are each located on one side of the first chamber S1 on the second axis A2 perpendicular to the first axis A1.

Because the temperature above the display module 4 (near the position of the first fan F1 in FIG. 3) is higher during actual use. Therefore, as shown in FIG. 4, in the present embodiment, the first air flow W1 can be controlled by the first fan F1 to enter the heat exchanger 5 through the opening above the heat exchanger 5 (see the opening of the first flow channels 51 on the left side of the heat exchanger 5 in FIG. 2) and leave from the bottom of the heat exchanger 5 and circulate into the second channel S21 again, at the same time make the control of the second fan F2 so that the direction of the second airflow W2 flowing through the heat exchanger 5 is opposite to the direction of the first airflow W1. In this way, the display module 4 can have better heat dissipation efficiency.

There is no restriction on the material of the heat exchanger 5 and can be made of materials with better heat conductivity, such as metal. The detailed configuration or specific shape of the first flow channels 51 and the second flow channels 52 can be adjusted or changed according to the requirements. Considering the function of the heat exchanger 5, the heat exchanger 5 in the present embodiment actually constitutes a member separating the second chamber S2 and the third chamber S3, so it should be understood that in the embodiment not shown in the figures, the specific shape of the heat exchanger 5 may, for example, be changed to a plate on the wall between the second chamber S2 and the third chamber S3, and the plate has finned structures on the surface of one side facing different chambers.

Further, from the above description, it can be understood that the first chamber S1 and the third chamber S3 are both chambers communicated to the outside of the housing 1, thus, in the embodiment not shown there in the figures, the arrangement of the heat exchanger 5 and the surrounding wall 13 can be changed so that the first chamber S1 and the third chamber S3 are communicated, and the position of the second fan F2 can be directly arranged in the first chamber S1 and located at the entrance or exit of the heat exchanger 5 to generate second air flow W2. The second airflow W2 leaving the heat exchanger 5 will be discharged out from the first chamber S1 together with the third airflow W3.

Although the number of heat exchanger 5 in the above exemplified embodiments is two, it should be understood that the number of heat exchangers 5 (such as one or more than three) in other embodiments can be adjusted according to requirements, and the number, shape or position of the third chamber S3 can be modified accordingly, and the configuration of the second fan F2 can be modified.

In the display device of the present invention uses a display module to separate a first chamber communicated to the exterior of the housing and a second chamber located between the display module and the cover plate and not communicated to the exterior of the housing and discharges heat from the second chamber to the exterior of the housing by a heat exchanger. Therefore, both surfaces of the display module (the display side and the backside of the display module), which serve as the separator, can dissipate heat and have good heat participation capability, and dust, dirt, moisture, etc., can be prevented from entering into the second chamber between the display module and the cover plate, and the display quality is good. In addition, from another perspective, since a first channel separating the main board from the backside of the display module is provided in the first chamber that can be connected to the outside of the outer housing, and since the other side of the main board is close to the outside of the outer housing, both surfaces of the main board (or the space provided therein) can easily exchange heat with the outside of the outer housing, and thus have good heat dissipation performance.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A display device, comprising:
a housing, having an accommodation space and an opening;
a cover plate, covering the opening;
a main board, arranged in the accommodation space and opposite the cover plate;
a display module, arranged in the accommodation space and electrically connected to the main board, wherein the display module has a display side and a backside opposite to each other, and the display side is located between the cover plate and the backside; and
a heat exchanger, located in the accommodation space;
wherein the accommodation space comprises a first chamber and a second chamber, the display module separates the first chamber and the second chamber, the heat exchanger is located in the second chamber, the first chamber is communicated to an outside of the housing and comprises a first channel located between the main board and the backside, the second chamber is not communicated to the outside of the housing and comprises a second channel located between the cover plate and the display side.

2. The display device according to claim 1, wherein the display module has a backlight assembly, and the main board is adapted for controlling the backlight assembly.

3. The display device according to claim 2, wherein the first channel completely separates the main board from the backside.

4. The display device according to claim 1, wherein the second chamber further comprises a third channel located at a periphery of the backside, and the third channel surrounds the first chamber and communicates with the second chamber.

5. The display device according to claim 1, wherein the cover plate, the display module, and the main board are arranged along a first axis, the housing further has a third chamber in the accommodation space, the third chamber is on one side of the first chamber respective to a second axis perpendicular to the first axis and is adjacent to the heat exchanger, the third chamber is communicated to the outside of the housing and does not communicate to the first chamber and the second chamber.

6. The display device according to claim 5, wherein the heat exchanger comprises a plurality of first flow channels spaced from each other and a plurality of second flow channels spaced from each other, the first flow channels and the second flow channels are arranged alternatively, the first flow channels are communicated to the second chamber, and the second flow channels are communicated to the third chamber.

7. The display device according to claim 6, further comprising:
a first fan, arranged in the second chamber, wherein the first fan is adapted for generating a first airflow flowing through the first flow channel; and
a second fan, arranged in the third chamber, wherein the second fan is adapted for generating a second airflow flowing through the second flow channel, and a direction of the first airflow is opposite to a direction of the second airflow in the heat exchanger.

8. A display device, comprising:
a housing, having an accommodation space and an opening communicated with each other;
a cover plate, covering the opening;
a main board, arranged in the accommodation space and opposite the cover plate;
a display module, arranged in the accommodation space and electrically connected to the main board, wherein the display module has a display side and a backside opposite to each other, and the display side is located between the cover plate and the backside; and
a heat exchanger, located in the accommodation space;
wherein the accommodation space comprises a first chamber and a second chamber separated from each other, the heat exchanger is located in the second chamber, the first chamber is communicated to an outside of the housing and comprises a first channel located between the main board and the backside, the second chamber is not communicated to the outside of the housing and comprises a second channel located between the cover plate and the display side, the display module comprises a backlight assembly and a control assembly, the control assembly is arranged on the main board, and the first channel completely separates the main board from the backside.

9. The display device according to claim 8, wherein the display module separates the first chamber and the second chamber, the backside is adjacent to the first channel, and the display side is adjacent to the second channel.
